(19) United States
(12) Patent Application Publication
(10) Pub. No.: US 2026/0211306 A1
(43) Pub. Date: Jul. 23, 2026

(54) PROJECTION-TYPE IMAGE DISPLAY APPARATUS

(71) Applicant: Panasonic Projector & Display Corporation, Osaka (JP)

(72) Inventors: Takumi YAMAGUCHI, Osaka (JP); Yoshinobu NAKAJIMA, Kyoto (JP); Kento ISHIMURO, Osaka (JP); Atsuyoshi HASHIMOTO, Nara (JP); Hideo FUKUDA, Osaka (JP)

(21) Appl. No.: 19/572,081

(22) Filed: Mar. 19, 2026

Related U.S. Application Data
(63) Continuation of application No. PCT/JP2024/033651, filed on Sep. 20, 2024.

(30) Foreign Application Priority Data
Sep. 22, 2023 (JP) 2023-158417

(51) Int. Cl. G03B 21/16; G03B 21/14

(52) U.S. Cl. CPC G03B 21/16; G03B 21/145

(57) ABSTRACT

A projection-type image display apparatus includes a light source, an optical modulator, a projection lens assembly, a power supply board, a sealed housing, a heat exchanger, a partition, and a fan. The optical modulator modulates the light from the light source to generate image light. The projection lens assembly has a plurality of lenses and projects the image light. The power supply board drives and controls the light source. The sealed housing houses the light source, the power supply board, the optical modulator, and the projection lens assembly. The heat exchanger exchanges heat between gas inside the sealed housing and gas outside the sealed housing. The partition is disposed inside the sealed housing and divides the inside of the sealed housing into a first space and a second space. The fan sequentially sends the gas inside the sealed housing from the heat exchanger through the first space to the second space.

### CROSS REFERENCE TO RELATED APPLICATION

This is a continuation application of International Application No. PCT/JP2024/033651, with an international filing date of Sep. 20, 2024, which claims priority of Japanese Patent Application No. 2023-158417 filed on Sep. 22, 2023, the content of which is incorporated herein by reference.

### BACKGROUND

### Technical Field

The present invention relates to a projection-type image display apparatus.

### Background Art

Conventionally, there has been a projection-type image display apparatus that modulates illumination light from a light source into image light using an optical modulator and projects the modulated image light. A digital micromirror device (DMD) or a liquid crystal element is used as the optical modulator. Such projection-type image display apparatuses are used in various indoor locations. An example of such a projection-type image display apparatus is the projection-type image display apparatus (projector) disclosed in WO 2019/225679.

### SUMMARY

However, when a projection-type image display apparatus is used outdoors, the amount of dust entering the projection-type image display apparatus is greater than when it is used indoors, and rain can also cause water to infiltrate into the apparatus. This can sometimes shorten the service life of the projection-type image display apparatus.

An object of the present disclosure is to provide a projection-type image display apparatus configured to suppress reduction in service life even when used outdoors.

A projection-type image display apparatus according to the present disclosure comprises: a light source that emits light; an optical modulator that modulates the light from the light source to generate image light; a projection lens assembly having a plurality of lenses and projecting the image light; a power supply board that drives and controls the light source; a sealed housing that houses the light source, the power supply board, the optical modulator, and the projection lens assembly; a heat exchanger that exchanges heat between gas inside the sealed housing and gas outside the sealed housing; a partition that is disposed inside the sealed housing and divides the inside of the sealed housing into a first space and a second space; and a fan that sequentially sends the gas inside the sealed housing from the heat exchanger through the first space to the second space.

The present disclosure can provide a projection-type image display apparatus configured to suppress reduction in service life even when used outdoors.

### BRIEF DESCRIPTION OF THE DRAWINGS

FIG. 1 is an external perspective view of a projection-type image display apparatus according to a first embodiment of the present invention;

FIG. 2 is a plan view showing the configuration of the projection-type image display apparatus according to the first embodiment with the top panel removed;

FIG. 3 is a longitudinal cross-sectional view of a heat exchanger;

FIG. 4 is a perspective view of a projection lens assembly;

FIG. 5 is a perspective view showing the configuration of an optical modulator and liquid cooling;

FIG. 6 is an explanatory diagram showing the configuration of a liquid cooling system; and

FIG. 7 is an explanatory diagram illustrating the flow of gas inside a sealed housing of the projection-type image display apparatus.

### DETAILED DESCRIPTION

Hereinafter, embodiments will be described in detail with reference to the accompanying drawings. However, unnecessarily detailed explanations may be omitted. For example, detailed explanations of well-known matters or repeated explanations of substantially the same configuration may be omitted. This is to avoid unnecessary redundancy in the following description and to facilitate understanding by those skilled in the art.

The accompanying drawings and the following description are provided to enable those skilled in the art to fully understand the present disclosure, and are not intended to limit the subject matter described in the claims.

### Embodiment

### [1-1. Configuration of Projection-Type Image Display Apparatus]

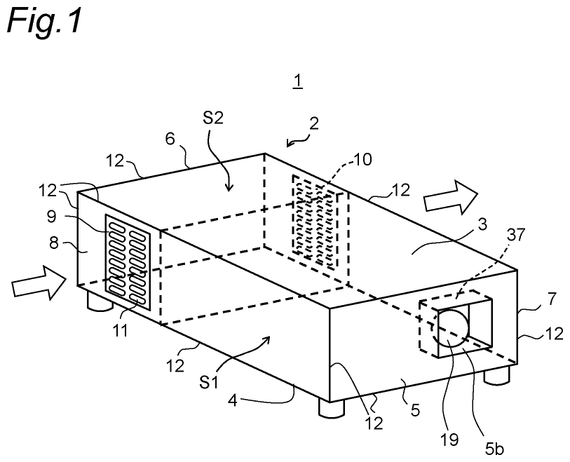

A projection-type image display apparatus 1 according to a first embodiment will be described with reference to FIG. 1. FIG. 1 is a perspective view of the appearance of the projection-type image display apparatus 1 according to the first embodiment. The projection-type image display apparatus 1 according to the first embodiment is, for example, a so-called three-chip DMD projector that uses three DMDs. Liquid crystal elements may be used instead of the DMDs.

The projection-type image display apparatus 1 of the first embodiment includes a housing 2. The housing 2 has a substantially rectangular parallelepiped shape and includes a frame 12 that forms each edge of the rectangular parallelepiped. The housing 2 further includes a top plate 3 and a bottom plate 4, and four side plates 5, 6, 7, and 8 that face each other. The frame 12 supports the top plate 3, the bottom plate 4m, and the side plates 5 to 8, each made of metal or resin, and the top plate 3, the bottom plate 4m, and the side plates 5 to 8 are fixed to the frame 12. The housing 2 may also include the metal top plate 3, the bottom plate 4m, and the side plates 5 to 8, which may be connected by welding without the frame 12. Image light is projected from the side plate 5. The side plates 5 and 6 face each other. The side plate 7 is connected to the side plates 5 and 6 via the frame 12, and has an air intake 9 through which outside air flows into the housing 2. The side plate 8 is connected to the side plates 5 and 6 via a frame 12, and has an air outlet 10 through which outside air that has flowed into the housing 2 flows out again to the outside of the housing 2. The air intake 9 and the air outlet 10 each have a plurality of apertures 11. The top plate 3 is detachably fastened to the four side plates 5 to 8. A sealed space S1 and an unsealed space S2 are arranged within the housing 2. The degree of sealing of the sealed space S1 is a liquid-tight state preventing inflow of liquid from the outside. Therefore, dust or dirt intrusion into the sealed space S1 is also suppressed.

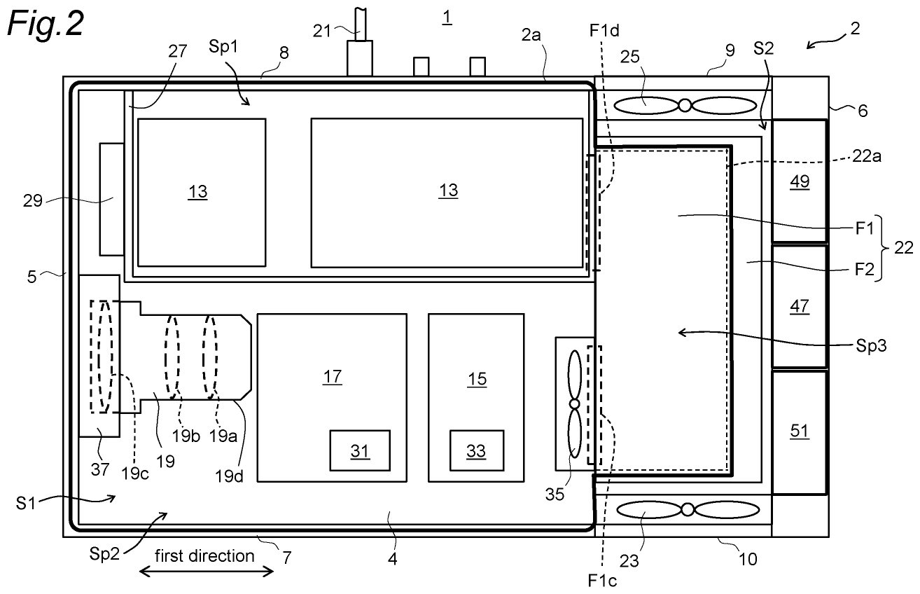

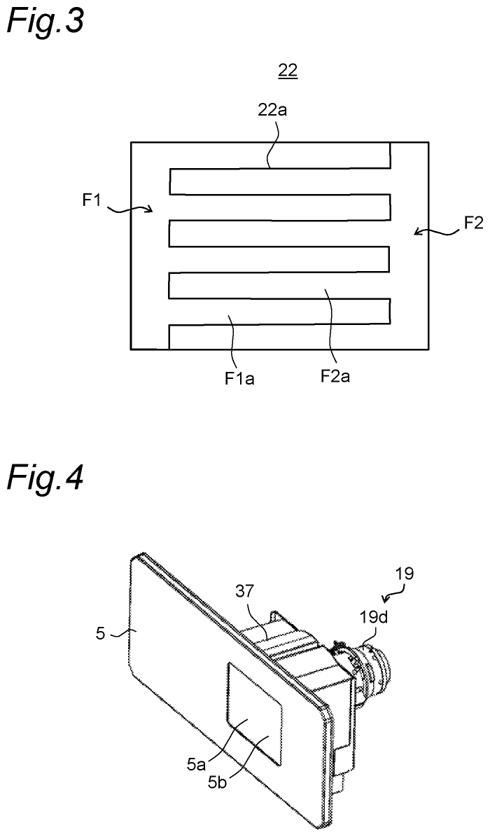

Next, reference is made to FIG. 2. FIG. 2 is a plan view showing the configuration of the projection-type image display apparatus 1 according to the embodiment with the top panel 3 removed.

The projection-type image display apparatus 1 includes a power supply board 13, a light source 15, an optical modulator 17, and a projection lens assembly 19. The power supply board 13, the light source 15, the optical modulator 17, and the projection lens assembly 19 are arranged in the sealed space S1.

The power supply board 13 converts power supplied from an external power source via a cable 21 into direct current and supplies the driving power to the projection-type image display apparatus 1. The power supply board 13 also controls power supplied to the light source 15, thereby controlling the amount of light emitted from the light source 15.

The power supply boards 13 each have an integrated circuit that can be implemented using semiconductor elements or the like, and can be configured, for example, with a microcomputer, CPU, MPU, GPU, DSP, FPGA, or ASIC. Each power supply board 13 implements a predetermined function by reading data and programs stored in a built-in memory section (not shown) and performing various arithmetic processing. The memory section can be implemented, for example, with a hard disk drive (HDD), SSD, RAM, DRAM, ferroelectric memory, flash memory, magnetic disk, or a combination thereof.

The light source 15 includes, for example, plural laser light sources and a phosphor wheel. For example, laser light in the blue wavelength range emitted from the plural laser light sources is branched and enters the phosphor wheel, where it is converted into laser light in the yellow wavelength range. The laser light in the yellow wavelength range and the laser light in the blue wavelength range are mixed to generate white light, which is emitted from the light source 15 to the optical modulator 17 via a relay optical system. The relay optical system includes plural lenses and mirrors, and guides the white light emitted from the light source 15 to the optical modulator 17.

The optical modulator 17 modulates the incident white light in accordance with an input video signal to generate video light, and outputs this video light to the projection lens assembly 19. The optical modulator 17 outputs colored light in accordance with an image signal synchronized with each colored light transmitted from a signal board included in the power supply board 13. The optical modulator 17 includes a light separation element (e.g., a prism or a dichroic mirror) that separates the incident white light into plural colored lights, an optical modulator 17a that modulates each of the separated colored lights in accordance with the video signal, and a light combining element (e.g., a prism) that combines the modulated colored lights into video light. The light separation element and the light combining element may be the same prism.

The optical modulator 17a may be, for example, a DMD that changes the angle of a micromirror to change the traveling direction of light, or a liquid crystal element. In the embodiment, an example of a DMD will be described as the optical modulator 17a.

The projection lens assembly 19 includes a plurality of lenses 19a, 19b, and 19c and a barrel 19d that supports each lens, and projects the image light incident from the optical modulator 17 onto a screen (not shown) in an enlarged form. In the embodiment, the projection lens assembly 19 is described as including three lenses for the sake of simplicity, but is not limited to this and may include more lenses. The arrangement direction of the plurality of lenses 19a, 19b, and 19c is defined as a first direction.

The signal board of the power supply board 13 controls the angle of the micromirror of each optical modulator 17a to a first angle or a second angle in synchronization with the input image signal. The light reflected at the first angle is emitted as image light, and the light reflected at the second angle is absorbed as unnecessary light.

The projection-type image display apparatus 1 further includes a heat exchanger 22 and fans 23 and 25. The fans 23 and 25 are arranged within the space S2.

The heat exchanger 22 includes a flow passage F1 communicating with the sealed space S1 and a flow passage F2 communicating with the space S2, and heat exchange occurs between the flow passage F1 and the flow passage F2. The flow passage F1 and the flow passage F2 are separated by a partition 22a. The partition 22a is, for example, a metal plate. The heat exchanger 22 includes flow passages F1a and F2a that alternately overlap each other, and high-temperature gas flowing through the flow passage F1a is cooled by outside air flowing through the flow passage F2a. The heat exchanger 22 may have a configuration in which plural fins protrude from the flow passage F1 into the flow passage F2, or may use a heat pipe instead of the partition 22a or fins to exchange heat. The flow passage F1 has an air intake F1c communicating with a second space Sp2 via a fan 35 and an air outlet F1d communicating with a first space Sp1.

The fan 25 draws in outside air through the air intake 9 and sends it to the flow passage F2 of the heat exchanger 22. The fan 23 exhausts the gas that has flowed out of the flow passage F2 of the heat exchanger 22 to the outside through the air outlet 10.

### [1-2. Configuration Inside the Sealed Space S1]

The sealed space S1 is a space surrounded by a portion of each of the top plate 3, bottom plate 4, and side plates 7 and 8, the side plate 5, and the partition 22a of the heat exchanger 22. A sealed housing 2a is composed of a portion of each of the top plate 3, bottom plate 4, and side plates 7 and 8, the side plate 5, and the partition 22a of the heat exchanger 22. Sealing members such as packing are arranged between the frame 12 and the top plate 3 and the side plates 5, 7, and 8, and the sealing is maintained when the top plate 3 and the side plates 5 to 8 are fixed to the frame 12.

The sealed space S1 within the sealed housing 2a is divided into the first space Sp1, the second space Sp2, and a third space Sp3. The first space Sp1 and the second space Sp2 are separated by a partition 27. The third space Sp3 is the space within the heat exchanger 22. The partition 27 is made of a metal or resin wall material. The lower end of the partition 27 is connected to the bottom plate 4, and the upper end of the partition 27 is connected to the top plate 3.

The power supply substrate 13 is disposed in the first space Sp1. A heat receiving portion 29 is disposed at the boundary between the first space Sp1 and the second space Sp2, and is disposed, for example, on the partition 27. The gas in the first space Sp1 flows into the second space Sp2 through the heat receiving portion 29, and the heat receiving portion 29 absorbs heat from the air flowing from the first space Sp1 to the second space Sp2. The heat receiving portion 29 is, for example, a radiator.

The projection lens assembly 19, the optical modulator 17, and the light source 15 are arranged in the second space Sp2. The optical modulator 17 has a heat receiving portion 31, and the light source 15 has a heat receiving portion 33. The heat receiving portion 31 absorbs heat from the optical modulator 17, and the heat receiving portion 33 absorbs heat from the light source 15. The heat receiving portions 31 and 33 are each a metal plate, such as a copper plate.

The fan 35 is disposed between the light source 15 and the heat exchanger 22. The fan 35 draws in gas from the second space Sp2 and causes the gas to flow into the flow passage F1 of the heat exchanger 22.

Reference is made to FIGS. 2 and 4. FIG. 4 is a perspective view of the projection lens assembly 19. A cover 37 is disposed to surround the side surface of the tip of the barrel 19d on the projection side of the projection lens assembly 19. The cover 37 is connected to the bottom plate 4 and the side plate 5, and supports the tip of the barrel 19d on the projection side. The cover 37 is connected to the side plate 5 via a cushioning material such as sponge.

The side plate 5 has an opening 5a on an extension of the projection direction of the barrel 19d of the projection lens assembly 19. A transparent member 5b is disposed to cover the opening 5a from the inside of the side plate 5. The transparent member 5b is a colorless, transparent member that transmits image light, and is, for example, a glass plate or a resin member. The transparent member 5b is arranged on an extension of the tip side of the barrel 19d of the projection lens assembly 19, and the image light projected from the projection lens assembly 19 passes through the transparent member 5b.

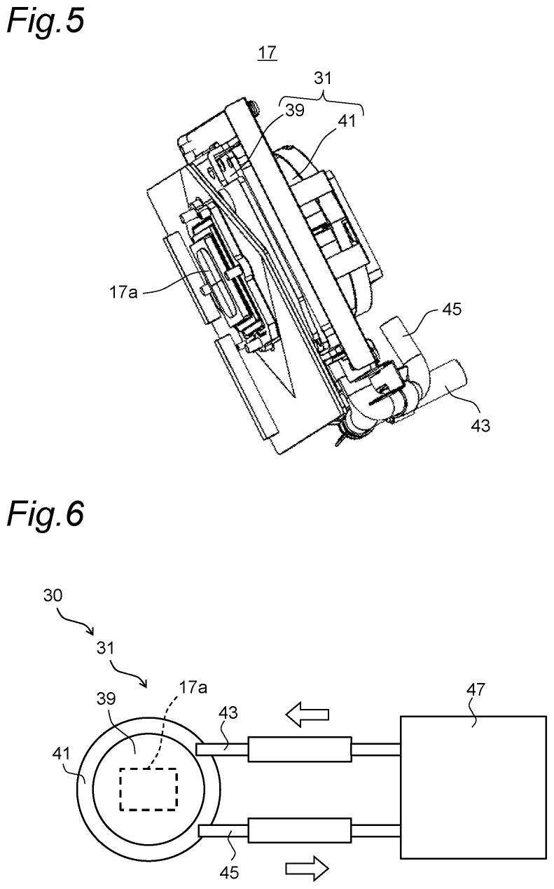

Reference is made to FIGS. 2, 5, and 6. FIG. 5 is a perspective view showing the configuration of the optical modulator 17a and liquid cooling. FIG. 6 is an explanatory diagram showing the configuration of a liquid cooling system 30. The liquid cooling system 30 includes the heat receiving portion 31, an inflow pipe 43, an outflow pipe 45, and a radiator 47. The heat receiving portion 31 includes a heat receiving plate 39 and a flow path 41.

One surface of the heat receiving plate 39 is in contact with the rear surface of the optical modulator 17a via grease, and receives the heat generated by driving the optical modulator 17a. The other surface of the heat receiving plate 39 is in contact with the flow path 41, and the heat of the heat receiving plate 39 is dissipated to the flow path 41.

The coolant flows through the flow path 41, and heat from the heat receiving plate 39 is transferred to the coolant in the flow path 41. The heat receiving portion 31 includes the inflow pipe 43 through which the coolant flows into the flow path 41, and the outflow pipe 45 through which the coolant flows out of the heat receiving portion 31. The coolant that flows in from the inflow pipe 43 absorbs heat from the optical modulator 17a and increases in temperature. The heat receiving portion 31 has a built-in pump, and the coolant whose temperature has increased flows out from the flow path 41 through the outflow pipe 45 and into the radiator 47. The coolant is cooled in the radiator 47, and the cooled coolant circulates back to the heat receiving portion 31.

Referring to FIG. 2, the radiator 47 and radiators 49 and 51 are arranged along the side plate 6 in the space S2. Similar to the liquid cooling system 30, a liquid-cooling system is configured in which the coolant circulates between the radiator 49 and the heat receiving portion 29. Heat absorbed by the heat receiving portion 29 is dissipated in the radiator 49 via the coolant. Similar to the liquid cooling system 30, a liquid-cooling system is configured in which the coolant circulates between the radiator 51 and the heat receiving portion 33. Heat absorbed by the heat receiving portion 33 is dissipated in the radiator 51 via the coolant. By including such a liquid-cooling system, the projection-type image display apparatus 1 can directly cool the gas that cools the light source 15, the optical modulator 17, and the power supply board 13, which are high-heat sources, using gas outside the sealed housing 2a via liquid cooling, thereby reducing the amount of heat required for air cooling by the heat exchanger 22. This allows the size of the heat exchanger 22 to be reduced, thereby achieving overall compactness of the projection-type image display apparatus 1.

### [1-3. Cooling Air Flow]

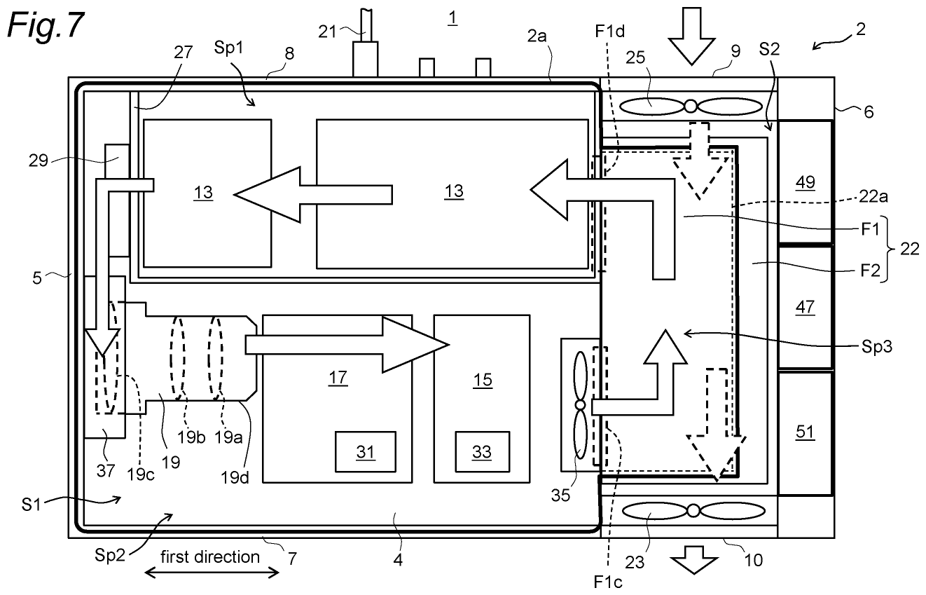

Next, the flow of gas within the sealed space S1 of the projection-type image display apparatus 1 according to the embodiment will be described with reference to FIG. 7. FIG. 7 is an explanatory diagram illustrating the flow of gas within the sealed housing 2a of the projection-type image display apparatus 1. The gas flowing within the sealed space S1 is, for example, air.

Outside air is drawn in through the air intake 9 by the fan 25 and flows into the flow passage F2 of the heat exchanger 22. The gas flowing through the flow passage F1 of the heat exchanger 22, which is the third space Sp3 of the sealed space S1, is cooled by the outside air flowing through the flow passage F2. The cooled gas flows into the first space Sp1 from the air outlet F1d of the flow passage F1 of the heat exchanger 22. The gas that flows into the first space Sp1 cools the power supply board 13. The gas that has been heated by the power supply board 13 flows from the first space Sp1 to the second space Sp2 through the heat receiving portion 29. The heat receiving portion 29 absorbs heat from the gas passing through, so the gas is cooled again.

The cooled gas collides with the side plate 5, changes its flow direction, and flows through the projection lens assembly 19 along the surface of the cover 37, cooling the lenses 19a to 19c of the projection lens assembly 19 via the barrel 19d. Because the cover 37 prevents gas from flowing on the projection side of the lens 19c, it is possible to prevent the cooling air from causing fluctuations in the projected image light.

The gas that has cooled the projection lens assembly 19 passes through the optical modulator 17 to cool optical elements such as lenses and prisms. The gas that has cooled the optical modulator 17 further passes through the light source 15 to cool optical elements such as a phosphor wheel and a collimator lens.

The gas that has cooled the light source 15 is forced to flow out through the air intake F1c of the flow passage F1 of the heat exchanger 22 by the fan 35. Inside the heat exchanger 22, heat exchange occurs between the gas, which has been heated by passing through the sealed space S1, and the outside air. The heated outside air is then exhausted to the outside through the flow passage F2 of the heat exchanger 22 and the air outlet 10 by the fan 23. In this way, the gas that has flowed out from the third space Sp3 of the heat exchanger 22 through the air outlet F1d into the first space Sp1 passes through the power supply board 13, and further passes through the projection lens assembly 19, the optical modulator 17, and the light source 15 in the second space Sp2, and flows into the third space Sp3 through the air intake F1c of the heat exchanger 22. This circulates and flows sequentially within the sealed space S1, thereby efficiently cooling the sealed space S1. In this way, by connecting the gas flow path within the sealed space S1 in a single loop from the air outlet F1d to the air intake F1c of the heat exchanger 22 and arranging the objects to be cooled in order on the flow path, it is possible to minimize the flow path required within the sealed space S1. This makes it possible to eliminate space other than where the heat exchanger 22 is located, thereby reducing wasted space and achieving compactness of the housing 2.

### [2. Effects, Etc.]

As described above, the projection-type image display apparatus 1 of the embodiment comprises: the light source 15 that emits light; the optical modulator 17 that modulates the light from the light source 15 to generate image light; the projection lens assembly 19 having a plurality of lenses 19a to 19c and projecting the image light; the power supply board 13 that drives and controls the light source 15; the sealed housing 2a that houses the light source 15, the power supply board 13, the optical modulator 17, and the projection lens assembly 19; the heat exchanger 22 that exchanges heat between the gas inside the sealed housing 2a and the gas outside the sealed housing 2a; the partition 27 that is disposed inside the sealed housing 2a and divides the inside of the sealed housing 2a into the first space Sp1 and the second space Sp2; and the fan 35 that sequentially sends the gas inside the sealed housing 2a from the heat exchanger 22 through the first space Sp1 to the second space Sp2.

The sealed housing 2a houses the light source 15, the power supply board 13, the optical modulator 17, and the projection lens assembly 19, which reduces the intrusion of dust and water into the light source 15, the power supply board 13, the optical modulator 17, and the projection lens assembly 19, thereby suppressing a shortened service life of the projection-type image display apparatus 1. In particular, because the power supply board 13 is also housed within the sealed housing 2a, deterioration can also be reduced even when used outdoors. Furthermore, the interior of the sealed housing 2a is divided into the first space Sp1 and the second space Sp2 by the partition 27, and the gas inside the sealed housing 2a cooled by the heat exchanger 22 is sent sequentially from the first space Sp1 to the second space Sp2, creating a unidirectional flow of cooling air within the sealed housing 2a, thereby increasing cooling efficiency.

Furthermore, since the cover 37, which covers at least a portion of the periphery of the lens 19c on the projection side of the projection lens assembly 19, is connected to the sealed housing 2a, it is possible to reduce the air inside the sealed housing 2a from flowing to the projection side of the lens 19c on the projection side of the projection lens assembly 19, thereby reducing fluctuations in the projected image light.

Furthermore, the gas cooled by the heat exchanger 22 flows from the heat exchanger 22 into the power supply board 13. The gas that has passed through the power supply board 13 flows into the projection lens assembly 19 from a first direction that intersects with the arrangement direction of the plural lenses 19a to 19c in the projection lens assembly 19. The gas that has passed through the projection lens assembly 19 flows into the heat exchanger 22. The cover 37 extends in a direction that intersects with the first direction.

Since the cover 37 extends in a direction intersecting with the first direction intersecting with the arrangement direction of the lenses 19a to 19c in the projection lens assembly 19, the gas flows along the cover 37. This makes it possible to reduce gas wraparound toward the projection-side lens 19c of the projection lens assembly 19, thereby reducing fluctuations in the projected image and reflection of dust into the image.

The projection-type image display apparatus 1 also includes the heat receiving portions 29, 31, and 33 arranged inside the sealed housing 2a, and the radiators 47, 49, and 51 arranged outside the sealed housing 2a and dissipating heat absorbed by the heat receiving portions 29, 31, and 33. The heat receiving portions 29, 31, and 33 exchange heat with the radiators 49, 47, and 51, respectively, via liquid. This further improves the cooling effect inside the sealed housing 2a.

Furthermore, the heat receiving portion 33 absorbs heat from the light source 15. This makes it possible to further improve the cooling effect for the light source 15.

Furthermore, the heat receiving portion 31 absorbs heat from the optical modulator 17. This makes it possible to further improve the cooling effect for the optical modulator 17.

Furthermore, the power supply board 13 is disposed in the first space Sp1, and the projection lens assembly 19, the optical modulator 17, and the light source 15 are disposed in the second space Sp2. Since only the power supply board 13 is disposed in the first space Sp1, the cooling effect of the power supply board 13 can be improved by the gas cooled by the outside air.

Furthermore, the heat receiving portion 29 is disposed at the boundary between the first space Sp1 and the second space Sp2, and absorbs heat from the gas flowing from the first space Sp1 to the second space Sp2. This allows the gas, which has been heated by cooling the power supply board 13, to be cooled by the heat receiving portion 29 as it flows from the first space Sp1 to the second space Sp2. The cooled air flows again into the second space Sp2, thereby further improving the cooling effect for the projection lens assembly 19, the optical modulator 17, and the light source 15, which are disposed in the second space Sp2.

### Other Embodiments

As described above, the embodiment has been described as an example of the technology of the present disclosure. For this purpose, the accompanying drawings and detailed description have been provided. Therefore, the components described in the accompanying drawings and detailed description may include not only components essential for solving the problem, but also components that are not essential for solving the problem in order to exemplify the above technology. Hence, the fact that these non-essential components are described in the accompanying drawings or detailed description should not be construed as immediately indicating that these non-essential components are essential.
(1) In the above-described embodiment, the sealed space S1 is a liquid-tight space that suppresses intrusion of dust and other particles and prevents intrusion of liquid such as water from the outside. However, this is not limitative. The sealed space S1 may be an airtight space that blocks the inflow and outflow of gases from the outside. In this case, the gas in the sealed space S1 is not limited to air, and helium or argon may also be used.
(2) In the above-described embodiment, the heat receiving portion 29 is disposed at the boundary between the first space Sp1 and the second space Sp2. However, this is not limitative. The heat receiving portion 29 may be omitted.
(3) In the above-described embodiment, the cover 37 surrounds the entire side surface of the tip of the barrel 19d of the projection lens assembly 19 on the projection side, but this is not limitative. The cover 37 surrounds at least a portion of the side surface of the tip of the barrel 19d of the projection lens assembly 19 on the projection side, thereby suppressing inflow of gas into the tip of the projection lens assembly 19. The cover 37 may be, for example, a wall standing upright from the bottom plate 4 between the projection lens assembly 19 and the heat receiving portion 29, or may have an inverted L-shape, standing upright from the bottom plate 4 and extending along the side plate 5 in a direction orthogonal to the arrangement direction of the plural lenses 19a to 19c.

Furthermore, since the above-described embodiment is intended to illustrate the technology of the present disclosure, various changes, permutations, additions, omissions, etc. may be made within the scope of the claims or their equivalents. Furthermore, it is also possible to combine the components described in the above embodiment to create new embodiments.

### Overview of Embodiments

(1) A projection-type image display apparatus of the present disclosure comprises: a light source that emits light; an optical modulator that modulates the light from the light source to generate image light; a projection lens assembly having a plurality of lenses and projecting the image light; a power supply board that drives and controls the light source; a sealed housing that houses the light source, the power supply board, the optical modulator, and the projection lens assembly; a heat exchanger that exchanges heat between gas inside the sealed housing and gas outside the sealed housing; a partition that is disposed inside the sealed housing and divides the inside of the sealed housing into a first space and a second space; and a fan that sequentially sends the gas inside the sealed housing from the heat exchanger through the first space to the second space.

Since the sealed housing houses the light source, the power supply board, the optical modulator, and the projection lens assembly, it is possible to reduce the intrusion of dust and water into the light source, the power supply board, the optical modulator, and the projection lens assembly, thereby extending the service life of the projection-type image display apparatus.
(2) The projection-type image display apparatus of (1) comprises a cover that at least partially covers a periphery of the lens located foremost on the projection side of the projection lens assembly, the cover being connected to the sealed housing.

Since the cover that at least partially covers a periphery of the lens located foremost on the projection side of the projection lens assembly is connected to the sealed housing, it is possible to reduce the air inside the sealed housing from flowing past the lens located foremost on the projection side of the projection lens assembly, thereby reducing fluctuations in the projected image light. “The cover is connected to the sealed housing” does not only mean that the cover is directly connected to the sealed housing, but also includes connection via a sponge or the like.
(3) In projection-type image display apparatus of (1) or (2), the gas cooled by the heat exchanger flows from the heat exchanger into the power supply board. The gas that has passed through the power supply board flows into the projection lens assembly from a first direction intersecting the direction of arrangement of the plurality of lenses in the projection lens assembly. The gas that has passed through the projection lens assembly flows into the heat exchanger. The cover extends in a direction intersecting the first direction.
(4) The projection-type image display apparatus of any one of (1) to (3) comprises: a heat receiving portion disposed inside the sealed housing; and a radiator disposed outside the sealed housing and configured to radiate heat absorbed by the heat receiving portion, wherein the heat receiving portion exchanges heat with the radiator via a liquid.
(5) In the projection-type image display apparatus of (4), the heat receiving portion absorbs heat from the light source.
(6) In the projection-type image display apparatus of (4) or (5), the heat receiving portion absorbs heat from the optical modulator.
(7) In the projection-type image display apparatus of any one of (1) to (6), the power supply board is disposed in the first space, and the projection lens assembly, the optical modulator, and the light source are disposed in the second space.
(8) In the projection-type image display apparatus of (7), the heat receiving portion is disposed at a boundary between the first space and the second space and absorbs heat from a gas flowing from the first space to the second space.

The present disclosure is applicable to a projection-type image display apparatus that projects image light generated by modulating light from a light source.

### Explanations of Letters or Numerals

1 projection-type image display apparatus
2 housing
2a sealed housing
3 top plate
4 bottom plate
5, 6, 7, 8 side plate
5a opening
5b transparent member
9 air intake
10 air outlet
11 aperture
13 power supply board
15 light source
17 optical modulator
19 projection lens assembly
19a, 19b, 19c lens
19d barrel
21 cable
22 heat exchanger
22a partition
23, 25 fan
27 partition
29, 31, 33 heat receiving portion
30 liquid cooling system
35 fan
37 cover
39 heat receiving plate
41 flow pass
43 inflow pipe
45 outflow pipe
47, 49, 51 radiator
F1, F2 flow passage
F1c air intake
F1d air outlet
S1 closed space
S2 space
Sp1 first space
Sp2 second space
Sp3 third space

What is claimed is

1. A projection-type image display apparatus comprising:
a light source that emits light;
an optical modulator that modulates the light from the light source to generate image light;
a projection lens assembly having a plurality of lenses and projecting the image light;
a power supply board that drives and controls the light source;
a sealed housing that houses the light source, the power supply board, the optical modulator, and the projection lens assembly;
a heat exchanger that exchanges heat between gas inside the sealed housing and gas outside the sealed housing;
a partition that is disposed inside the sealed housing and divides the inside of the sealed housing into a first space and a second space; and
a fan that sequentially sends the gas inside the sealed housing from the heat exchanger through the first space to the second space.

2. The projection-type image display apparatus according to claim 1, comprising
a cover that at least partially covers a periphery of the lens located foremost on the projection side of the projection lens assembly,
the cover being connected to the sealed housing.

3. The projection-type image display apparatus according to claim 2, wherein
the gas cooled by the heat exchanger flows from the heat exchanger into the power supply board, wherein
the gas that has passed through the power supply board flows into the projection lens assembly from a first direction intersecting the direction of arrangement of the plurality of lenses in the projection lens assembly, wherein
the gas that has passed through the projection lens assembly flows into the heat exchanger, and wherein
the cover extends in a direction intersecting the first direction.

4. The projection-type image display apparatus according to claim 1, comprising:
a heat receiving portion disposed inside the sealed housing; and
a radiator disposed outside the sealed housing and configured to radiate heat absorbed by the heat receiving portion, wherein
the heat receiving portion exchanges heat with the radiator via a liquid.

5. The projection-type image display apparatus according to claim 4, wherein
the heat receiving portion absorbs heat from the light source.

6. The projection-type image display apparatus according to claim 4, wherein
the heat receiving portion absorbs heat from the optical modulator.

7. The projection-type image display apparatus according to claim 4, wherein
the power supply board is disposed in the first space, and wherein
the projection lens assembly, the optical modulator, and the light source are disposed in the second space.

8. The projection-type image display apparatus according to claim 7, wherein
the heat receiving portion is disposed at a boundary between the first space and the second space and absorbs heat from a gas flowing from the first space to the second space.
